(19) United States
(12) Patent Application Publication
(10) Pub. No.: US 2015/0097213 A1
(43) Pub. Date: Apr. 9, 2015

(54) IMAGE SENSOR AND PIXELS INCLUDING VERTICAL OVERFLOW DRAIN

(71) Applicant: OMNIVISION TECHNOLOGIES, INC., Santa Clara, CA (US)

(72) Inventors: Gang Chen, San Jose, CA (US); Duli Mao, Sunnyvale, CA (US); Dyson H. Tai, San Jose, CA (US)

(73) Assignee: OMNIVISION TECHNOLOGIES, INC., Santa Clara, CA (US)

(21) Appl. No.: 14/046,645

(22) Filed: Oct. 4, 2013

(51) Int. Cl. H01L 27/148; H01L 27/146

(52) U.S. Cl. CPC H01L 27/14887; H01L 27/14683
USPC 257/228; 438/60

(57) ABSTRACT

Embodiments of an apparatus comprising a pixel array including a plurality of pixels formed in a substrate having a front surface and a back surface, each pixel including a photosensitive region formed at or near the front surface and extending into the substrate a selected depth from the front surface. A filter array is coupled to the pixel array, the filter array including a plurality of individual filters each optically coupled to a corresponding photosensitive region, and a vertical overflow drain (VOD) is positioned in the substrate between the back surface and the photosensitive region of at least one pixel in the array.

### TECHNICAL FIELD

The disclosed embodiments relate generally to image sensors and in particular, but not exclusively, to backside-illuminated image sensors including a vertical overflow drain.

### BACKGROUND

A typical image sensor includes various optical and electronic elements formed on a front side of the sensor. The optical elements include at least an array of individual pixels to capture light incident on the image sensor, while the electronic elements include transistors. Although the optical and electronic elements are formed on the front side, an image sensor can be operated as a frontside-illuminated (FSI) image sensor or a backside-illuminated (BSI) image sensor. In an FSI image sensor, light to be captured by the pixels in the pixel array is incident on the front side of the sensor, while in a BSI image sensor the light to be captured is incident on the back side of the sensor.

Compared to FSI image sensors, BSI image sensors drastically improve fill factor, quantum efficiency and cross talk, hence improving the sensor's overall optical performance. BSI technology also makes it possible to continuously scale CMOS pixel size down to sub-0.11 microns. But unlike FSI, BSI blooming issues have not been satisfactorily solved due to three major obstacles. First, BSI sensors intrinsically have no highly-doped bulk region to recombine extra photo-electrons. Next, BSI outperforms FSI for pixel sizes of 1.75 micron and below, but unlike FSI there is less space to add anti-blooming features into already very small pixel cells. Finally, BSI image sensors collect photons from the back side, but the silicon substrate in a BSI sensor is thinner than the substrate in an FSI image sensor, meaning there is little vertical space in traditionally-designed sensors to put vertical overflow drains between the back side and the photodetector to capture the extra photoelectrons.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross-sectional view of a portion of an embodiment of a backside-illuminated (BSI) image sensor.

FIG. 2 is a cross-sectional view of an embodiment of a backside-illuminated (BSI) image sensor.

FIG. 3A is a plan view of an embodiment of a backside-illuminated (BSI) image sensor including a vertical overflow drain (VOD).

FIG. 3B is a cross-sectional view of the embodiment of a backside-illuminated (BSI) image sensor of FIG. 3A taken substantially along section line B-B.

FIGS. 4A-4B are a cross-sectional view and a plan view, respectively, of another embodiment of a backside-illuminated (BSI) image sensor including a vertical overflow drain (VOD).

FIGS. 5A-5B are a cross-sectional view and a plan view, respectively, of another embodiment of a backside-illuminated (BSI) image sensor including a vertical overflow drain (VOD).

FIGS. 6A-6B are a cross-sectional view and a plan view, respectively, of another embodiment of a backside-illuminated (BSI) image sensor including a vertical overflow drain (VOD).

FIG. 7A is a cross-sectional view of a generalized embodiment of a backside-illuminated (BSI) image sensor including a vertical overflow drain (VOD).

FIG. 7B shows different embodiments of filter pattern minimal repeating units (MRUs) that can be used in embodiments of a BSI image sensor including a vertical overflow drain (VOD).

FIG. 8 is a schematic drawing of an embodiment of an image sensor including a color filter array.

### DETAILED DESCRIPTION OF THE ILLUSTRATED EMBODIMENTS

Embodiments are described of an apparatus, system and method for backside-illuminated image sensors including a vertical overflow drain. Specific details are described to provide a thorough understanding of the embodiments, but one skilled in the relevant art will recognize that the invention can be practiced without one or more of the described details, or with other methods, components, materials, etc. In some instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one described embodiment. Thus, appearances of the phrases “in one embodiment” or “in an embodiment” in this specification do not necessarily all refer to the same embodiment. Furthermore, the particular features, structures, or characteristics can be combined in any suitable manner in one or more embodiments.

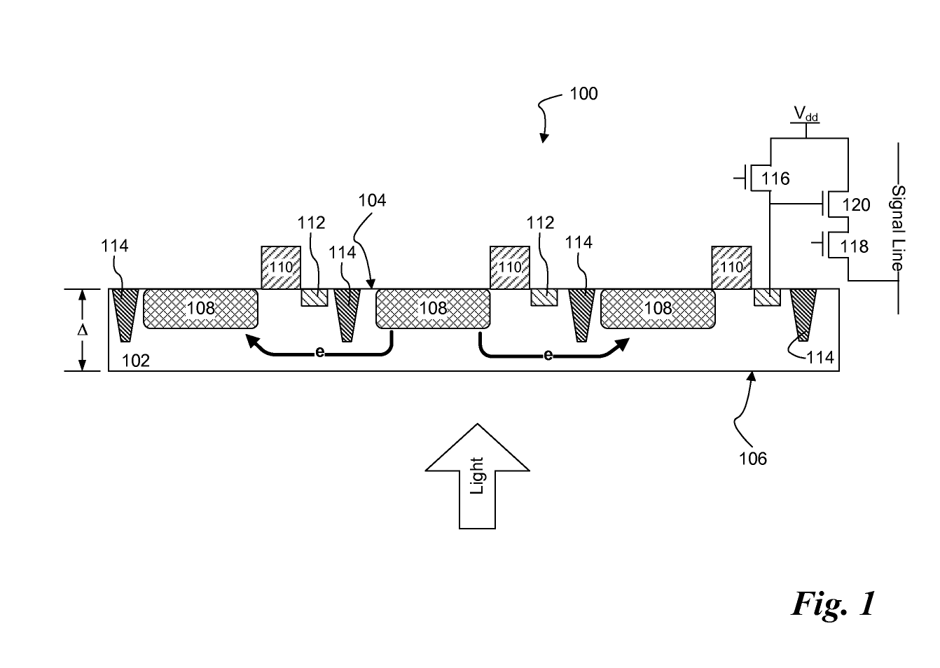

FIG. 1 illustrates an embodiment of a portion of a backside-illuminated image sensor 100. The illustrated portion of image sensor 100 includes three pixels formed in a substrate 102 that has a front surface 104, a back surface 106, and a thickness Δ between the front surface and the back surface. The pixels are formed in, on, or near front surface 104. Each pixel includes a photosensitive region 108, a floating node 112, and a transfer gate 110 that, when switched on, transfers charge (i.e., photoelectrons) accumulated in photosensitive region 108 to the floating node. Shallow trench isolations (STIs) 114 can be used to physically separate and electrically isolate each individual pixel from adjacent pixels in the pixel array.

During an integration period, also referred to as an exposure period or accumulation period, photosensitive regions 108 receive incident light through the back surface, as shown by the arrow, and generate charge (i.e., photoelectrons) in the depletion volume of photosensitive region 108. After the charge is generated it is held as free photoelectrons in photosensitive region 108. At the end of the integration period, the photoelectrons held in photosensitive region 108 (i.e., the signal) are transferred into floating node 112 by applying a voltage pulse to turn on transfer gate 110. When the signal has been transferred to floating node 112, transfer gate 110 is turned off again for the start of another integration period. After the signal has been transferred from photosensitive region 108 to floating node 112, the signal held in each floating node is used to modulate an amplification transistor 120, which is also known as a source-follower transistor. An address transistor 118 is used to address the pixel and to selectively read out the signal onto the signal line. Finally, after readout through the signal line, a reset transistor 116 resets floating node 112 and photosensitive region 108 to a reference voltage, which in one embodiment is V_{dd}.

In a pixel that is subjected to a high amount of light during the exposure period—because it happens to correspond to a very bright part of the image, for example—photosensitive region 108 quickly becomes “full” of charge carriers (e.g., photoelectrons). When the photosensitive region becomes full, excess charge carriers begin to migrate from photosensitive region 108 toward the photosensitive regions of neighboring pixels, as shown by the arrows labeled “e” in the figure. This migration of charge carriers from one pixel to adjacent pixels is known as blooming. Blooming distorts the signals from adjacent pixels: in the resulting image, the brightest spot expands to the surrounding area and makes the picture inaccurate. STIs 114 are formed in substrate 102 to attempt to block this migration of charge carriers, but the STIs are not completely effective and their effectiveness in BSI image sensors is lower than in FSI image sensors.

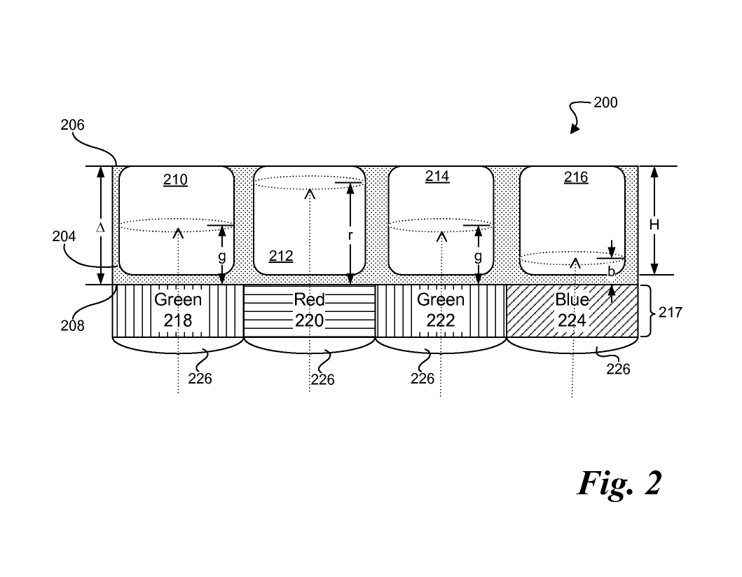

FIG. 2 illustrates an embodiment of a backside illuminated (BSI) image sensor 200. BSI image sensor 200 includes a substrate 204 having a front surface 206 and a back surface 208 separated from each other by a distance Δ corresponding to the thickness of the substrate. Photosensitive regions 210, 212, 214, and 216 are formed in substrate 204. In the illustrated embodiment, photosensitive regions 210-216 are formed at or near front surface 206 and extend into substrate 204 by a depth H measured from front surface 206. Depth H can be less than or equal to Δ in different embodiments. Other elements that are typically formed on the front surface of an image sensor—such as transistor gates, floating diffusions, etc., as shown in FIG. 1—can be present in, on, or near front surface 206 in embodiments of BSI image sensor 200 but for clarity these elements are omitted from the drawing.

A filter array 217 is positioned on back surface 208 so that each individual filter in filter array 217 is coupled to a corresponding photosensitive region. In the illustrated embodiment, filter array 217 contains a plurality of individual primary color filters, with each individual color filter optically coupled to an individual photosensitive region: green filter 218 is optically coupled to photosensitive region 210, red filter 220 to photosensitive region 212, green filter 222 to photosensitive region 214, and blue filter 224 to photosensitive region 216. Microlenses 226 can be formed on the individual filters as shown to help focus light incident on the back side of the sensor into the respective photosensitive regions.

In operation of BSI image sensor 200, light is incident on the backside of the image sensor. The incident light enters through microlenses 226 and travels through filters 218-224, which allow only their respective primary colors of light to enter substrate 204. Each primary color of light corresponds to a range of wavelengths associated with that color. When the different primary light colors penetrate substrate 204, they enter the corresponding photosensitive region 210-216, where they are absorbed and where they generate photoelectrons. Different colors of light are absorbed at different depths in substrate 204 and/or the respective photosensitive regions. In the illustrated embodiment, green light is absorbed in photosensitive regions 210 and 214 at a distance g from back surface 208, blue light is absorbed in photosensitive region 216 at distance b from back surface 208, and red light is absorbed in photosensitive region 212 at a distance r from back surface 208. In doped silicon substrates, light nearer the ultraviolet end of the spectrum (i.e., shorter wavelengths) is absorbed at smaller depths than light nearer the infrared end of the spectrum (i.e., longer wavelengths). In the illustrated embodiment, then, the relative sizes of absorption distances b, g, and r are substantially given by b<g<r. In other embodiments, for example in substrates made of different materials, the relative magnitudes of absorption depths of the different colors can be different than illustrated.

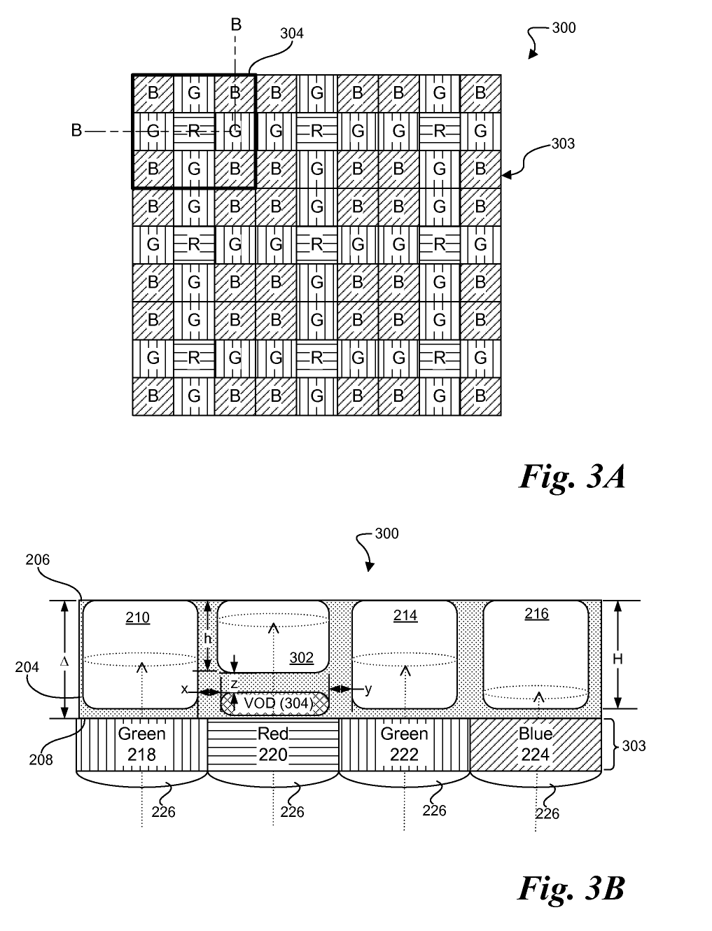

FIGS. 3A-3B illustrate an embodiment of a backside illuminated (BSI) image sensor 300. As shown in FIG. 3A, a color filter array 303 is coupled to the backside of a pixel array. CFA 303 includes a plurality of individual filters, each of which is optically coupled to a corresponding individual pixel in the pixel array. CFAs assign a separate primary color to each pixel by placing a filter of that primary color over the pixel. Thus, for example, it is common to refer to a pixel as a “clear pixel” if it has no filter or is coupled to a clear (i.e., colorless) filter, as a “blue pixel” if it is coupled to a blue filter, as a “green pixel” if it is coupled to a green filter, or as a “red pixel” if it is coupled to a red filter. As photons pass through a filter of a certain primary color to reach the pixel, only wavelengths that fall within the wavelength range of that primary color pass through. All other wavelengths are absorbed.

The individual filters in CFA 303 are arrayed in a pattern, usually formed by tiling together a plurality of minimal repeating units (MRU) such as MRU 304. A minimal repeating unit is a repeating unit such that no other repeating unit has fewer individual filters. A given color filter array can include several different repeating units, but a repeating unit is not a minimal repeating unit if there is another repeating unit in the array that includes fewer individual filters. The illustrated embodiment includes red (R), green (G), and blue (B) filters arranged in the well-known Bayer pattern, which has three-by-three MRU 304 shown in the figure. In other embodiments, CFA 303 can include other colors in addition to, or instead of, R, G, and B. For example, other embodiments can include cyan (C), magenta (M), and yellow (Y) filters, clear (i.e., colorless) filters, infrared filters, ultraviolet filters, x-ray filters, etc. Other embodiments can also include a filter array with an MRU that includes a greater or lesser number of pixels than illustrated for MRU 304.

FIG. 3B illustrates a sectional view of BSI image sensor 300 taken substantially along section line B-B. BSI image sensor 300 is similar in many respects to BSI image sensor 200. Image sensor 300 includes a substrate 204 with a front surface 206 and a back surface 208 separated from each other by a distance Δ that is the thickness of the substrate. Photosensitive regions are formed at or near front surface 206, and a filter array, such as CFA 303 in one embodiment, is positioned on back surface 208 such that each individual filter is optically coupled to a corresponding individual photosensitive region. Microlenses 226 can be formed on the individual filters as shown to help focus light into the respective photosensitive areas.

The primary difference between image sensor 300 and image sensor 200 is the depth h of photosensitive region 302 that is coupled to red filter 220. In the illustrated embodiment, the depth h of photosensitive region 302, measured from front surface 206, is less than the depth H of photosensitive regions 210, 214, and 216 that capture green or blue light. The smaller depth h of photosensitive region 302 leaves an undoped region in substrate 204 between back surface 208 and photosensitive region 302. Because of red light is absorbed at a larger distance from back surface 208, the smaller depth h of photosensitive region 302 has minimal effect on the performance of the pixel.

A vertical overflow drain (VOD) 304 is positioned in the undoped region of substrate 204 between photosensitive region 302 and back surface 208. VOD 304 is positioned in substrate 204 such that it is at or near back surface 208 and is separated from photosensitive region 302 by distance z, separated from photosensitive region 210 by distance x, and separated from photosensitive region 214 by distance y. In the illustrated embodiment, distances y and x are substantially equal, indicating that VOD 304 is positioned substantially equidistant from the photosensitive areas surrounding photosensitive region 302, such as photosensitive regions 210 and 214.

In the illustrated embodiment, VOD 304 is substantially rectangular and covers a large part of the area under photosensitive region 302; in other words, for VOD 304 distances x, y and z are small. In other embodiments, distance z can be adjusted to regulate the flow of photoelectrons from photosensitive region 302 into VOD 304, and distances x and y can be adjusted to regulate the flow of excess electrons into VOD 304 from the photosensitive regions adjacent to photosensitive region 302. The illustrated structure can reduce blooming in neighboring photosensitive areas and can also reduce crosstalk by absorbing excess photoelectrons generated by adjacent pixels.

In an embodiment in which photosensitive regions 210, 302, 214, and 216 are n-doped regions, VOD 304 can also be an n-doped region. Similarly, in an embodiment in which photosensitive regions 210, 302, 214, 216 are p-doped regions, VOD 304 can be a p-doped region. In one embodiment VOD 304 can be formed in substrate 204 by implanting dopants from the back side using known implant-doping methods.

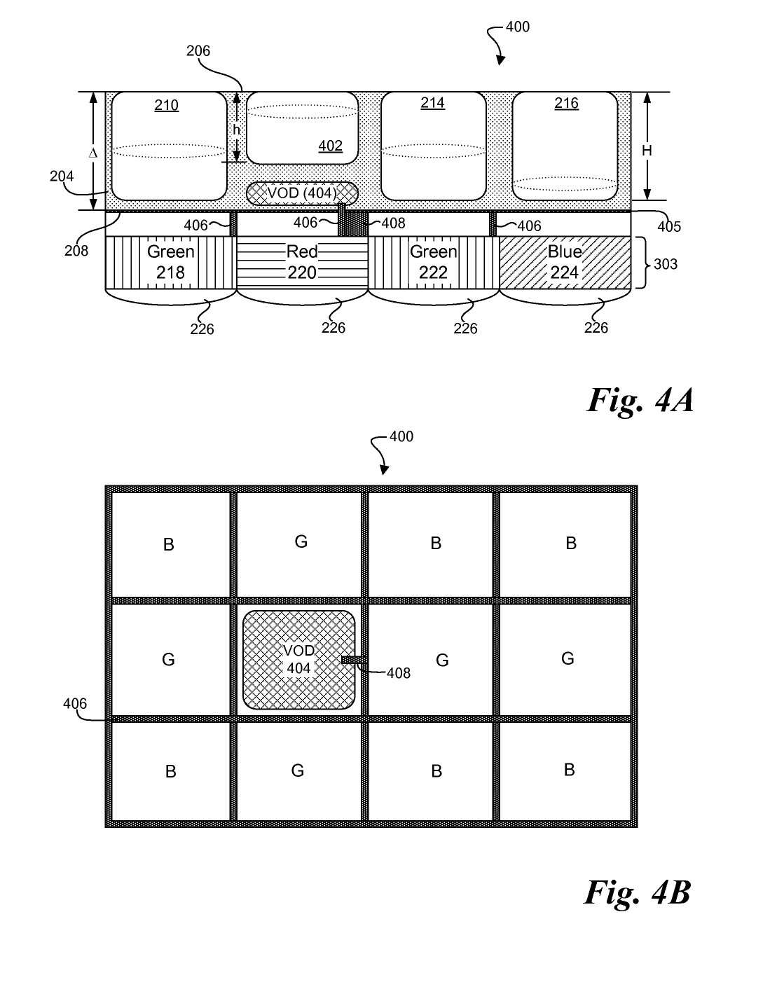

FIGS. 4A-4B illustrate another embodiment of a BSI image sensor 400. Image sensor 400 is similar in most respects to image sensor 300: photosensitive regions 210, 402, 214, 216 are formed in substrate 204 and a filter array such as CFA 303 is positioned on or over back surface 208 such that each filter in the array is optically coupled to a corresponding photosensitive region. Photosensitive region 402 has a depth h, measured from front surface 206, that is smaller than the depth H of photosensitive regions 210, 214, and 216, and a VOD 404 is formed in substrate 204 between photosensitive region 402 and back surface 208.

The primary difference between image sensors 400 and 300 is that image sensor 400 includes an electrically conductive grid 406 that is formed between the back surface 208 and CFA 303 and separated from back surface 208 by a dielectric layer 405. In one embodiment, conductive grid 406 can be formed of a metal, but in other embodiments the conductive grid can be formed of a conductive nonmetal, for example a doped or undoped semiconductor. VOD 404 is electrically coupled to grid 406, for example by a via 408, so that VOD 404 can be electrically grounded and excess electrons flowing into VOD 404 from adjacent photosensitive regions can be carried away through the conductive grid instead of migrating into neighboring photosensitive regions as shown in FIG. 1

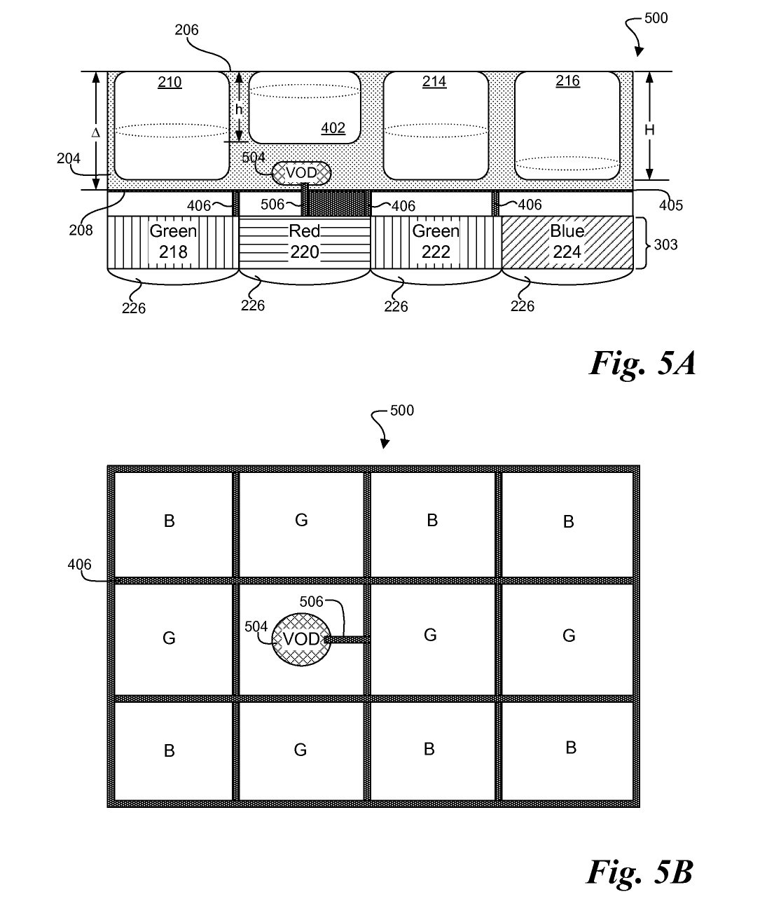

FIGS. 5A-5B illustrate another embodiment of a BSI image sensor 400. Image sensor 400 is similar in most respects to image sensor 300: photosensitive regions 210, 402, 214, 216 are formed in substrate 204 and a filter array such as CFA 303 is positioned on or over back surface 208 such that each filter in the array is optically coupled to a corresponding photosensitive region. Photosensitive region 402 has a depth h, measured from front surface 206, that is smaller than the depth H of photosensitive regions 210, 214, and 216, and a VOD 504 is formed in substrate 204 between photosensitive region 402 and back surface 208. Electrically conductive grid 406 is formed between the back surface 208 and CFA 303 and separated from back surface 208 by a dielectric layer 405. VOD 504 is electrically coupled to grid 406, for example by a via 506, so that VOD 504 can be electrically grounded and excess electrons flowing into VOD 504 from the photosensitive regions can be carried away instead of migrating into neighboring photosensitive regions as shown in FIG. 1.

The primary difference between image sensors 500 and 400 is the size and shape of VOD 504. Both the size and shape of VOD 504 can be tailored to regulate the flow of photoelectrons from neighboring photosensitive regions. In image sensor 500, VOD 504 is substantially circular instead of substantially rectangular, and is also substantially smaller than VOD 404. In other words, at least distances x and y (see FIG. 3) are substantially larger in image sensor 500 than they are an image sensor 400. In other embodiments, the shape of VOD 504 could be different, for example it could be elliptical, square, triangular, or any other polygon or non-polygon shape.

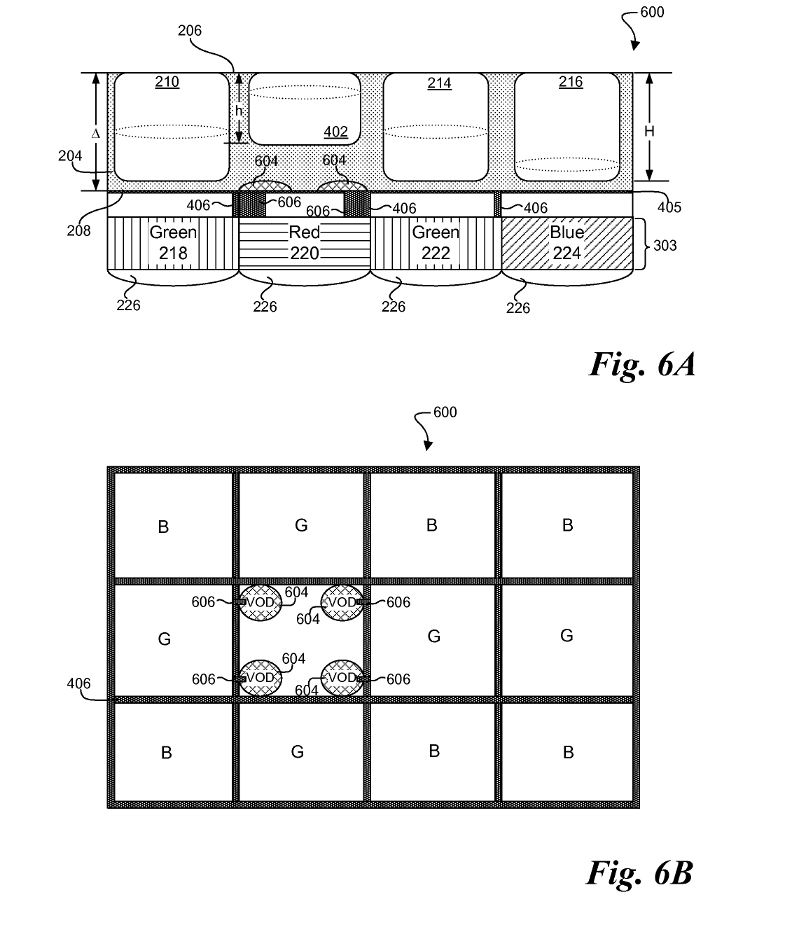

FIGS. 6A-6B illustrate another embodiment of a BSI image sensor 600. Image sensor 600 is similar in most respects to image sensor 400 and 500: photosensitive regions 210, 402, 214, 216 are formed in substrate 204 and a filter array such as CFA 303 is positioned on or over back surface 208 such that each filter in the array is optically coupled to a corresponding photosensitive region. Photosensitive region 402 has a depth h, measured from front surface 206, that is smaller than the depth H of photosensitive regions 210, 214, and 216, and a VOD 604 is formed in substrate 204 between photosensitive region 402 and back surface 208. An electrically conductive grid 406 is formed between the back surface 208 and CFA 303 and separated from back surface 208 by a dielectric layer, and VOD 604 is electrically coupled to grid 406, for example by vias 608, so that VOD 604 can be electrically grounded and excess electrons flowing into VOD 604 from the photosensitive regions can be carried away instead of migrating into neighboring photosensitive regions as shown in FIG. 1.

The primary difference between image sensor 600 and image sensors 400 and 500 is that in image sensor 600 VOD 604 is not a single contiguous region, but rather includes multiple non-contiguous regions. The illustrated embodiment shows a VOD made up of four non-contiguous regions 604, but in other embodiments VOD 604 can include less or more non-contiguous regions 604. As with the other embodiments, the size shape and distance of each non-contiguous region 604 can be varied to tailor the flow of excess photoelectrons into the VOD. Moreover, the illustrated embodiment shows VOD regions 604 positioned in a substantially rectangular pattern, but in other embodiments the non-contiguous VOD regions 604 could be positioned in other patterns.

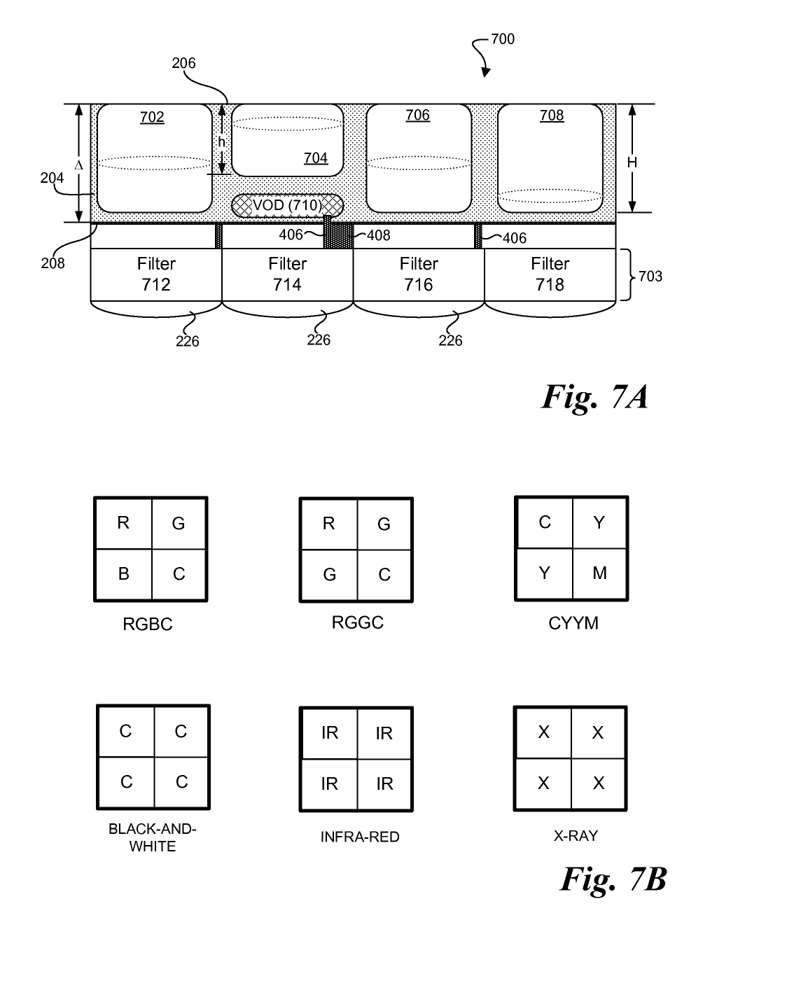

FIGS. 7A-7B illustrate a generalized embodiment of a BSI image sensor 700. Image sensor 700 is similar in most respects to image sensors 300-600: photosensitive regions 702, 704, 706, and 708 are formed in substrate 204 and a filter array such as CFA 703 is positioned on or over back surface 208 such that each filter in CFA 703 is optically coupled to a corresponding photosensitive region. Photosensitive region 704 has a depth h, measured from front surface 206, that is smaller than the depth H of photosensitive regions 702, 706, and 708, and a VOD 710 is formed in substrate 204 between photosensitive region 704 and back surface 208. An electrically conductive grid 406 is formed between the back surface 208 and CFA 703 and separated from back surface 208 by a dielectric layer, and VOD 710 is electrically coupled to grid 406, for example by vias 408, so that VOD 710 can be electrically grounded and excess electrons flowing into VOD 710 from the photosensitive regions can be carried away instead of migrating into neighboring photosensitive regions as shown in FIG. 1.

The primary difference between image sensor 700 and image sensors 300-600 is that image sensor 700 includes a generalized filter array 703. In CFAs 217 and 303, the CFA includes red, green, and blue filters as its primary colors and they are arranged in a Bayer pattern, and the substrate to which they are coupled the VOD is positioned under the photosensitive area corresponding to the red filter. But in image sensor 700 the filter array is more general. Filter array 703 includes filters 712-718, each of which can be any color, including colorless and “colors” outside the visible wavelengths, and all of which can be arranged in different patterns than in CFAs 217 and 303. Filters 712-718 need not have the previously illustrated colors, but can be of different colors and/or be arranged into different minimal repeating units.

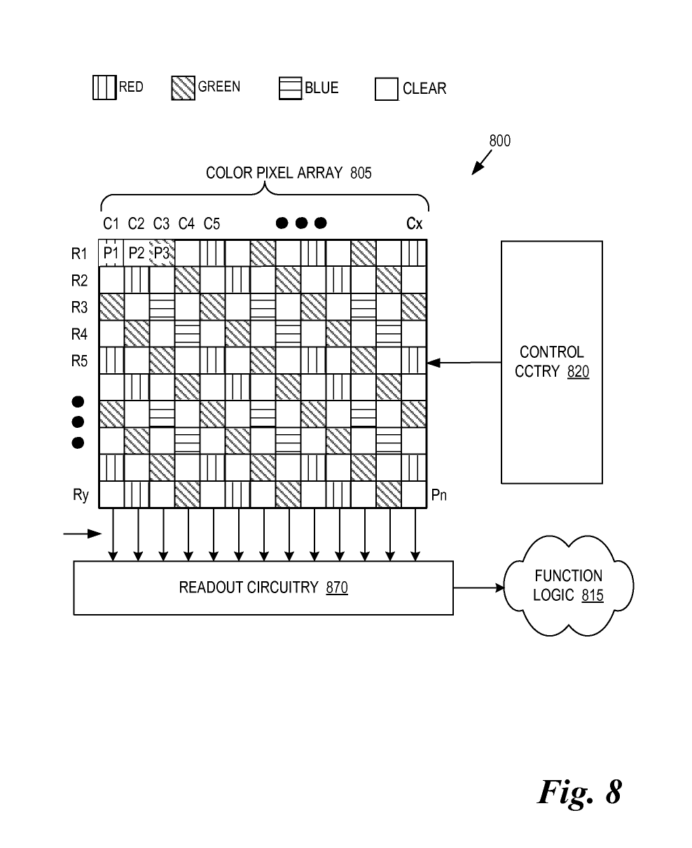

Moreover, embodiments of image sensor 700 need not position the vertical overflow drain under the photosensitive area optically coupled to the red filter, but can instead position the VOD under the photosensitive region 704 that is optically coupled to filter 714, whatever color filter 714 happens to be. Additionally, in the previously illustrated embodiments the particular pattern of the CFA result in all photosensitive regions being adjacent to a VOD. But in other embodiments, depending on the colors, the filter arrangement, and the particular filters where the VODs are placed, every photosensitive region in the array need not end up adjacent to a VOD. In the filter array illustrated in FIG. 8, for example, if the VODs are positioned under the photosensitive regions coupled to the red filters, every photosensitive region in the array will not end up adjacent to a VOD.

FIG. 7B illustrates various embodiments of MRUs that can be used to form filter array 703. In one embodiment, filter array 703 can be an RBGC array that includes red, green, blue, and clear (i.e., colorless) filters. In such a filter, the pixels optically coupled to red, green and blue filters are sensitive to light in those primary color wavelength ranges, while the pixels optically coupled to the clear filters are sensitive to a much broader range of wavelengths that can encompass the red, green and blue wavelength ranges. In another embodiment, filter array 703 can be an RGGC array that includes red, green, and clear filters. In such an embodiment, primary colors of light that don't have a specific filter present in the array can be extracted from the filters that are present. In another embodiment, filter array 703 can be a CYYM array including cyan, yellow, and magenta filters. In another embodiment, filter array 703 can be a monochromatic filter that includes only clear filters—in other words, a black-and-white filter array. In other monochromatic embodiments, filter array 703 can include infrared (IR) filters or x-ray (X) filters. Of course, other embodiments can use colors that are different than shown, and can use MRUs that are have more or less pixels than are shown and arranged differently than shown.

FIG. 8 illustrates an embodiment of a CMOS image sensor 800 including a color pixel array 805, readout circuitry 870 coupled to the pixel array, function logic 815 coupled to the readout circuitry, and control circuitry 820 coupled to the pixel array. Color pixel array 805 is a two-dimensional (“2D”) array of individual imaging sensors or pixels (e.g., pixels P1, P2 . . . , Pn) having X pixel columns and Y pixel rows. Color pixel array 805 can be implemented as a backside-illuminated pixel array including one or more VODs, as shown in FIGS. 3A-3B, 4A-4B, 5A-5B and/or 6A-6B. In one embodiment, each pixel in the array is a complementary metal-oxide-semiconductor (“CMOS”) imaging pixel. As illustrated, each pixel is arranged into a row (e.g., rows R1 to Ry) and a column (e.g., column C1 to Cx) to acquire image data of a person, place, or object, which can then be used to render a 2D image of the person, place, or object.

Color pixel array 805 assigns color to each pixel using a color filter array (“CFA”) coupled to the pixel array. In the illustrated embodiment, color pixel array 805 includes clear (i.e., colorless) pixels in addition to red (R), green (G) and blue (B) pixels, and they are arranged in a different pattern having a different MRU that pixel array 303 shown in FIG. 3A.

After each pixel in pixel array 805 has acquired its image data or image charge, the image data is read out by readout circuitry 870 and transferred to function logic 815 for storage, additional processing, etc. Readout circuitry 870 can include amplification circuitry, analog-to-digital (“ADC”) conversion circuitry, or other circuits. Function logic 815 can simply store the image data and/or manipulate the image data by applying post-image effects (e.g., crop, rotate, remove red eye, adjust brightness, adjust contrast, or otherwise). Function logic 815 can also be used in one embodiment to process the image data to correct (i.e., reduce or remove) fixed pattern noise.

Control circuitry 820 is coupled to pixel array 805 to control operational characteristic of color pixel array 805. For example, control circuitry 820 can generate a shutter signal for controlling image acquisition.

The above description of illustrated embodiments of the invention, including what is described in the abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention must be determined entirely by the following claims, which are to be construed in accordance with established doctrines of claim interpretation.

1. An apparatus comprising:
a pixel array including a plurality of pixels formed in a substrate having a front surface and a back surface, each pixel including a photosensitive region formed at or near the front surface and extending into the substrate a selected depth from the front surface;
a filter array coupled to the pixel array, the filter array including a plurality of individual filters each optically coupled to a corresponding photosensitive region;
a vertical overflow drain (VOD) positioned in the substrate between the back surface and the photosensitive region of at least one pixel in the array, wherein the at least one pixel has a photosensitive region with a smaller selected depth than the photosensitive regions of other pixels in the array.

2. (canceled)

3. The apparatus of claim 1 wherein each individual filter is designed to pass a first wavelength range or a second wavelength range.

4. The apparatus of claim 3 wherein the at least one pixel in the array is coupled to an individual color filter that passes the first wavelength.

5. The apparatus of claim 3 wherein the first wavelength range is absorbed in the photosensitive region at a greater distance from the back surface of the substrate than the second wavelength range.

6. The apparatus of claim 3 wherein the first wavelength range encompasses at least the second wavelength range.

7. The apparatus of claim 3 wherein the first wavelength range is longer than the second wavelength range.

8. The apparatus of claim 7 wherein the first wavelength range is red and the second wavelength range is blue or green.

9. The apparatus of claim 1 wherein each VOD is electrically coupled to ground.

10. The apparatus of claim 1, further comprising a metal grid formed between the color filter array and the back surface of the substrate.

11. The apparatus of claim 10, further comprising a via that electrically couples each VOD to the metal grid.

12. The apparatus of claim 1 wherein each VOD comprises a single contiguous region.

13. The apparatus of claim 1 wherein each VOD comprises a plurality of non-contiguous regions.

14. A process comprising:
forming a pixel array including a plurality of pixels in a substrate having a front surface and a back surface, each pixel including a photosensitive region formed at or near the front surface and extending into the substrate a selected depth from the front surface, wherein the photosensitive region of each pixel is optically coupled to an individual filter; and
forming a vertical overflow drain (VOD) in the substrate between the back surface and the photosensitive region of at least one pixel in the array, wherein the at least one pixel has a photosensitive region with a smaller selected depth than the photosensitive regions of other pixels in the array.

15. (canceled)

16. The process of claim 14 wherein each individual filter passes a first wavelength range or a second wavelength range.

17. The process of claim 16 wherein the at least one pixel in the array is coupled to an individual filter that passes the first wavelength range.

18. The process of claim 17 wherein the first wavelength range is absorbed in the photosensitive region at a greater distance from the back surface of the substrate than the second wavelength range.

19. The process of claim 16 wherein the individual filters that pass the first wavelength range or the second wavelength range are part of a color filter array coupled to the back surface of the pixel array.

20. The process of claim 16 wherein the first wavelength range encompasses at least the second wavelength range.

21. The process of claim 16 wherein the first wavelength range is longer than the second wavelength range.

22. The process of claim 21 wherein the first wavelength range is red and the second wavelength range is blue or green.

23. The process of claim 14, further comprising electrically coupling each VOD to ground.

24. The process of claim 14, further comprising forming a metal grid between the color filter array and the back surface of the substrate.

25. The process of claim 24, further comprising electrically coupling each VOD to the metal grid.

26. The process of claim 14 wherein each VOD comprises a single contiguous region.

27. The process of claim 14 wherein each VOD comprises a plurality of non-contiguous regions.
